(19) United States
(12) Patent Application Publication
(10) Pub. No.: US 2008/0196757 A1
(43) Pub. Date: Aug. 21, 2008

(54) SOLAR CELL AND SOLAR CELL MODULE

(75) Inventor: Yukihiro YOSHIMINE, Kobe City (JP)

Correspondence Address: MOTS LAW, PLLC, 1001 PENNSYLVANIA AVE. N.W., SOUTH, SUITE 600, WASHINGTON, DC, 20004, US

(73) Assignee: SANYO ELECTRIC CO., LTD., Moriguchi City (JP)

(21) Appl. No.: 12/029,551

(22) Filed: Feb. 12, 2008

(30) Foreign Application Priority Data
Feb. 19, 2007 (JP) JP2007-038650

(51) Int. Cl. H01L 31/0224; H01L 31/04; H01L 31/042

(52) U.S. Cl. 136/244; 136/252

(57) ABSTRACT

A photoelectric converter generates carriers by photoelectric conversion. A multiple finger electrodes are electrically coupled to the photoelectric converter. The finger electrodes collect carriers generated in the photoelectric converter. The finger electrodes contain a sintering conductive material as an essential ingredient. A bus-bar electrode is electrically coupled to the multiple finger electrodes. The bus-bar electrode collects the carriers from the finger electrodes. The bus-bar electrode contains a thermosetting conductive material as an essential ingredient.

### CROSS REFERENCE TO RELATED APPLICATIONS

This application claims priority based on 35 USC 119 from prior Japanese Patent Application No. P2007-038650 filed on Feb. 19, 2007, the entire contents of which are incorporated herein by reference.

### BACKGROUND OF THE INVENTION

1. Field of the Invention

The invention relates to a solar cell and a solar cell module. More specifically, the invention relates to: a solar cell including a photoelectric converter, a finger electrode and a bus-bar electrode, the electrodes formed on the photoelectric converter; and a solar cell module including multiple solar batteries provided between a top surface protector and a back surface protector and electrically interconnected with wiring tabs.

2. Description of Related Art

Solar cells directly convert sunlight, which is clean and inexhaustibly supplied, into electricity. For this reason, solar cells are expected to be new energy sources.

Each solar cell sheet generates an output of about several watts. Accordingly, a solar cell module in which multiple solar cells are electrically interconnected in series or in parallel is employed to install the solar cells for use as a power source for a house, a building, or the like.

A solar cell module includes multiple solar cells which are placed between an acceptance surface protector and a back surface protector, and which are electrically interconnected with wiring tabs. Each solar cell includes: a photoelectric converter; and a collector electrode which is formed above the photoelectric converter. Moreover, the collector electrode includes: an acceptance surface collector electrode formed on an acceptance surface side of the photoelectric converter; and a back surface collector electrode formed on a back surface side of the photoelectric converter. The tab is connected to the acceptance surface collector electrode of a first solar cell, and is also connected to the back surface collector electrode of a second solar cell adjacent to the first solar cell.

In a crystalline solar cell having, as a basic structure, a semiconductor pn junction formed by a thermal diffusion method, the collector electrodes are generally formed by baking a sintering conductive paste having low specific resistance. According to Japanese Patent Application Laid-open Publication No. 2006-156693, for example, silver paste containing silver powder, glass frit, an organic vehicle, and an organic solvent is used as the conductive paste.

The collector electrodes formed by use of the sintering conductive paste are not easily plastically deformable and are brittle in nature. Cracks and brittle fractures easily occur inside such a collector electrode when stress is applied.

Here, the tabs, the collector electrodes, and the photoelectric converter have mutually different linear expansion coefficients. Accordingly, stress is generated on an interface between the tab and the collector electrode, as well as on an interface between the collector electrode and the photoelectric conductor.

Therefore, cracks and brittle fractures may occur inside the collector electrodes due to an influence of the stress generated on the interface between the tab and the collector electrode, as well as on the interface between the collector electrode and the photoelectric conductor. Further, such an influence of the stress may also cause a crack and a brittle fracture even in the photoelectric converter.

Cracks and brittle fractures of the collector electrodes or the photoelectric converter cause deterioration in the output of the solar cell, and degrade reliability thereof.

### SUMMARY OF THE INVENTION

An aspect of the invention provides a solar cell and a solar cell module with enhanced reliability by relaxing an influence of stress generated inside collector electrodes.

Another aspect of the invention provides a solar cell that comprises a photoelectric converter configured to generate carriers by photoelectric conversion; multiple finger electrodes electrically coupled to the photoelectric converter and configured to collect carriers generated in the photoelectric converter, the finger electrodes containing a sintering conductive material as an essential ingredient; and a bus-bar electrode electrically coupled to the multiple finger electrodes and configured to collect the carriers from the finger electrodes, the bus-bar electrode containing a thermosetting conductive material as an essential ingredient.

The bus-bar electrode to which a tab is thermally bonded is formed by use of a thermosetting conductive paste. The bus-bar electrode formed by use of the thermosetting conductive paste has an easily deformable property, as compared to a bus-bar electrode formed by use of sintering conductive paste. For this reason, the bus-bar electrode is capable of relaxing stress generated on an interface between the tab and the bus-bar electrode, as well as on an interface between the bus-bar electrode and the photoelectric converter. As a result, it is possible to suppress occurrence of cracks or fractures in the bus-bar electrode or in the photoelectric converter.

Still another aspect of the invention provides a A solar cell module that comprises at least two solar cells, each comprising: a photoelectric converter configured to generate carriers by photoelectric conversion; a plurality of finger electrodes electrically coupled to the photoelectric converter and configured to collect carriers generated in the photoelectric converter, the finger electrodes containing a sintering conductive material as an essential ingredient; and a bus-bar electrode electrically coupled to the plurality of finger electrodes and configured to collect the carriers from the finger electrodes, the bus-bar electrode containing a thermosetting conductive material as an essential ingredient; a tab configured to electrically interconnect the solar cells by electrically connecting the bus-bar electrodes to one another; an acceptance surface protector provided on an acceptance surface side of the solar cells; and a back surface protector provided on a back surface side of the solar cells.

### BRIEF DESCRIPTION OF THE DRAWINGS

FIG. 1A is a cross-sectional view of solar cell module 100 before a module forming process, and FIG. 1B is a cross-sectional view of solar cell module 100 after the module forming process.

FIG. 2 is a top view of solar cell 10 according to an embodiment.

FIG. 3 is a cross-sectional view taken along the line A-A in FIG. 2.

FIG. 4A and FIG. 4B are views showing a method of manufacturing a solar cell module.

FIG. 5A and FIG. 5B are views showing the method of manufacturing a solar cell module.

FIG. 6A and FIG. 6B are views explaining the method of manufacturing a solar cell module according to the embodiment.

### DETAILED DESCRIPTION OF EMBODIMENTS

Embodiments of the invention are described with reference to the accompanying drawings. In the following description of the drawings, the same or similar constituents are designated by the same or similar reference numerals. However, it should be noted that the drawings are merely schematic, and that the invention is not limited to ratios of, e.g., dimensions in the drawings. Accordingly, actual dimensions should be determined in consideration of the following explanation. In addition, dimensional relations or ratios may vary among the drawings.

### Solar Cell and Solar Cell Module

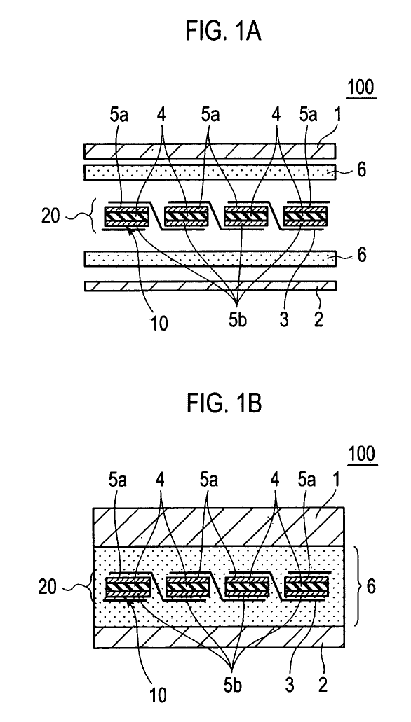

FIG. 1A is a cross-sectional view of solar cell module 100 before a module forming process. Meanwhile, FIG. 1B is a cross-sectional view of solar cell module 100 after the module forming process. When forming the module, it is possible to bond inner members together through a vacuum laminator while suppressing generation of air bubbles between respective members, for example.

As shown in FIG. 1B, solar cell module 100 includes solar cell strings 20, acceptance surface protector 1, back surface protector 2, and sealant 8. Solar cell module 100 includes multiple solar cells 10. Solar cells 10 are electrically interconnected with wiring tabs 3, and collectively constitute solar cell strings 20. Solar cells 10 are fixed with sealant 8 between acceptance surface protector 1 and back surface protector 2.

Solar cell 10 includes: acceptance surface collector electrode 5a disposed on an acceptance surface side; back surface collector electrode 5b disposed on a back surface side; and photoelectric converter 4 interposed between acceptance surface collector 5a and back surface collector electrode 5b. As for solar cell 10, it is possible to use a crystalline solar cell, for example. Here, the crystalline solar cell is a solar cell which has, as a basic structure, a semiconductor pn junction formed by a thermal diffusion method.

Photoelectric converter 4 generates carriers upon receipt of light on the acceptance surface side. The carriers mean a pair of a hole and an electron generated when incident light is absorbed by photoelectric converter 4. Photoelectric converter 4 has, as a basic structure, a semiconductor pn junction formed by the thermal diffusion method. Acceptance surface protector 1 is disposed on the acceptance surface side of solar cell strings 20. A material is used for acceptance surface protector 1, which material is configured to transmit the majority of light having a wavelength that can be absorbed by photoelectric converter 4. For example, glass having translucency and imperviousness, translucent plastics, and the like can be used for acceptance surface protector 1.

Acceptance surface collector electrode 5a and back surface collector electrode 5b are bonded to a light incident surface as well as a back surface of photoelectric conductor 4, and are configured to collect the photogenerated carriers from photoelectric converter 4. Acceptance surface collector electrode 5a and back surface collector electrode 5b may apply a material containing a conductive substance such as silver, aluminum, copper, nickel, tin, gold, or alloys of these materials. Here, the electrodes may be formed into a single layer structure containing any of these materials, or may be formed into a multilayer structure. In addition to the layer containing any of these conductive materials, the electrodes may further include a layer containing a translucent conductive oxide such as SNO₂, ITO, IWO or ZNO.

Tab 3 may apply a conductive material such as copper, which is formed into a thin plate or a stranded wire. A first end of tab 3 is connected to acceptance surface collector electrode 5a disposed on the acceptance surface side of first solar cell 10, while a second end of tab 3 is connected to back surface collector electrode 5b disposed on the back surface side of second solar cell 10 adjacent to first solar cell 10. Tab 3 may be thermally bonded to acceptance surface collector electrode 5a as well as to back surface collector electrode 5b, by means of a conductive adhesive such as solder or thermosetting resin. In this way, first solar cell 10 is electrically coupled to second solar cell 10 adjacent to first solar cell 10, and thus multiple solar cells are interconnected in series to constitute the solar cell strings.

Back surface protector 2 is disposed on the back surface side of the solar cell strings 20. As for back surface protector 2, for example, it is possible to use: a resin film such as a PET (Polyethylene Terephthalate) film or fluororesin film; a resin film provided with an evaporated film of a metal oxide such as silica or alumina; a metallic film such as an aluminum foil; and a laminated film of the foregoing material.

Sealant 8 seals solar cell strings 20 between acceptance surface protector 1 and back surface protector 2. Sealant 8 may be made of translucent resin. For example, sealant 8 may apply a resin material such as EVA (ethylene-vinyl acetate), PVB (polyvinyl butyral), silicone resin, urethane resin, acrylic resin, fluororesin, ionomer resin, silane modified resin, ethylene-acrylate copolymers, ethylene-methacrylate copolymers, polyethylene-based resin, polypropylene-based resin, acid-modified polyolefin-based resin or epoxy-based resin. It is also possible to blend two or more types of these resin materials.

Although solar cell module 100 is configured as described above, it is also possible to attach an Al frame (not shown) around solar cell module 100 in order to increase strength as the module, and thus to attach the module firmly to a mount.

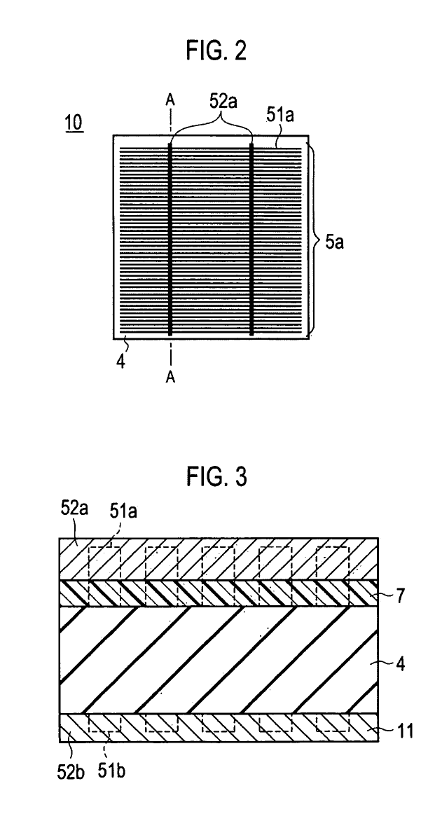

FIG. 2 is a plan view showing an upper face of the solar cell of this embodiment. Acceptance surface collector electrode 5a is formed above photoelectric converter 4 of solar cell 10, and acceptance surface collector electrode 5a includes: acceptance surface finger electrodes 51a; and acceptance surface bus-bar electrodes 52a. Acceptance surface finger electrodes 51a are collector electrodes configured to collect the carriers from photoelectric converter 4. As shown in the drawing, multiple acceptance surface finger electrodes 51a are formed in the shape of lines with a predetermined interval substantially on the entire range on the acceptance surface of photoelectric converter 4.

Here, acceptance surface finger electrodes 51a of this embodiment are formed by baking sintering conductive paste. The sintering conductive paste contains so-called ceramic paste. The sintering conductive paste includes, for example, silver paste containing silver powder, glass frit, an organic vehicle, and an organic solvent. Acceptance surface finger electrodes 51a are formed by coating the sintering conductive paste on anti-reflective film 7, and then by baking coated anti-reflective film 7 at a high temperature around 700° C. The sintering conductive paste penetrates anti-reflective film 7 by the action of glass frit. In this way, the paste is connected to photoelectric converter 4 and formed into acceptance surface finger electrodes 51a. This method is called a fire-through method.

Acceptance surface bus-bar electrodes 52a are collector electrodes configured to collect the carriers from multiple acceptance surface finger electrodes 51a. In this embodiment, acceptance surface bus-bar electrodes 52a are formed into lines with a predetermined interval so as to intersect acceptance surface finger electrodes 51a. Tabs 3 (not shown) are electrically coupled to acceptance surface bus-bar electrodes 52a.

Here, acceptance surface bus-bar electrodes 52a according to this embodiment are formed by thermally hardening a thermosetting conductive paste. The thermosetting conductive paste is resin paste applying thermosetting resin as binder. A silver paste formed by dispersing silver grains in an epoxy-based thermosetting resin solution is used as the thermosetting conductive paste, for example. Acceptance surface bus-bar electrodes 52a may be formed by coating the thermosetting conductive paste on the acceptance surface side of the anti-reflective film 7, and then by hardening the paste at a low temperature around 200° C.

FIG. 3 is an enlarged cross-sectional view taken along the line A-A in FIG. 2. In photoelectric conductor 4 of the solar cell of this embodiment, an n-type semiconductor layer is formed where n-type impurity is diffused in a p-type single-crystal or polycrystalline silicon substrate by a thermal diffusion method. That is, photoelectric converter 4 includes a semiconductor pn junction which is formed on the acceptance surface side of the silicon substrate. When light having predetermined energy is irradiated on the pn junction, the light is absorbed by electrons in a valence band in the pn junction area. Consequently, the electrons are excited beyond a band gap, and thereby formed into photoelectrons while holes are left over. A drift current is increased by generation of these photoelectrons, and then a thermal equilibrium state breaks up. The photoelectrons move to the n-type semiconductor layer, while the holes move to the p-type semiconductor layer, by means of an internal electric field formed in a depletion layer. Thus, an electromotive force is generated.

Anti-reflective film 7 and acceptance surface collector electrode 5a are formed on the acceptance surface side of the n-type semiconductor layer. It is possible to use SiN, SiO₂, ZnS, TiO₂, Si₃N₄, and the like for the anti-reflective film. Meanwhile, a p⁺-type diffused layer (not shown) including a p-type impurity diffused by the thermal diffusion method is formed on the back surface side of the silicon substrate. In this way, it is also possible to form a pp⁺ barrier layer. The structure including the pp⁺ barrier layer on the back surface side is provided so as to avoid recoupling of the electrons generated by the light acceptance on the back surface. This structure is called a BSF (back surface field) structure. Back surface collector electrodes 5b are formed on the back surface side of the p⁺-type diffused layer.

Finger electrodes 51a penetrate anti-reflective film 7 and are electrically coupled to photoelectric converter 4. Meanwhile, acceptance surface bus-bar electrodes 52a are formed above acceptance surface collector electrodes 5a, and are electrically coupled to finger electrodes 51a.

In this way, acceptance surface collector electrode 5a according to this embodiment includes: acceptance surface finger electrodes 51a formed by use of the sintering conductive paste; and acceptance surface bus-bar electrodes 52a formed by use of the thermosetting conductive paste. Moreover, acceptance surface finger electrodes 51a and acceptance surface bus-bar electrodes 52a are formed into comb shapes on the acceptance surface side of photoelectric converter 4. Note that, it is possible to use a printing method such as screen printing or offset printing for coating the sintering or thermosetting conductive paste.

As similar to acceptance surface collector electrode 5a, back surface collector electrode 5b according to this embodiment includes: back surface finger electrodes 51b formed by use of the sintering conductive paste; and back surface bus-bar electrodes 52b formed by use of the thermosetting conductive paste. Moreover, back surface finger electrodes 51b and back surface bus-bar electrodes 52b are formed into comb shapes on the back surface side of photoelectric converter 4, similarly to acceptance surface finger electrodes 51a and acceptance surface bus-bar electrodes 52a. Although the back surface collector electrode 5b in the above-described shape is used in this embodiment, it is also possible to use the collector electrodes in various other shapes without limitations to the foregoing. Accordingly, back surface collector electrode 5b may be formed in a wider area than acceptance collector electrode 5a, or may be formed so as to cover the entire surface on the back surface side of photoelectric converter 4.

### Method of Manufacturing Solar Cell Module

A method of manufacturing solar cell module 100 according to this embodiment is described with reference to the accompanying drawings. Solar cell module 100 includes, as the basic structure, the crystalline solar cells having the semiconductor pn junction formed by the thermal diffusion method.

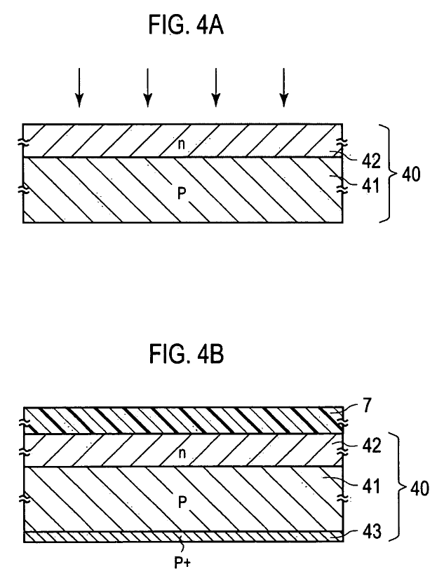

FIG. 4A is a view showing the method of manufacturing the solar cell module. First, p-type single-crystal or polycrystalline silicon substrate 40 is subjected to anisotropic etching in an alkaline solution in order to form fine irregularities on a surface thereof. Then, the surface of silicon substrate 40 is cleaned to remove foreign substances.

Next, n-type semiconductor layer 42 is formed on the acceptance surface side of silicon substrate 40 by diffusing an n-type impurity, by the thermal diffusion method. In this way, p-type semiconductor layer 41 and n-type semiconductor layer 42 are formed on silicon substrate 40, while the pn junction is formed on the acceptance surface side. It is possible to use P, Sb, Ti, and the like for the n-type impurity.

FIG. 4B is another view showing the method of manufacturing the solar cell module. P⁺-type diffused layer 43 is formed on the back surface side of silicon substrate 40 by diffusing a p-type impurity by the thermal diffusion method. In this way, the BSF structure is formed on the back surface side of silicon substrate 40. It is possible to use Al, As, In and the like for the p-type impurity.

Next, anti-reflective film 7 is formed by a plasma CVD method, on the acceptance surface side of n-type semiconductor layer 42. It is possible to use SiN, SiO₂, ZnS, TiO₂, Si₃N₄, and the like for anti-reflective film 7.

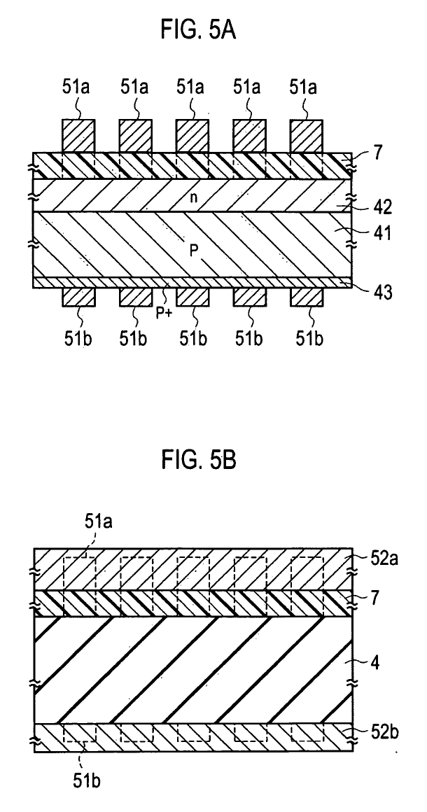

FIG. 5A is another view showing the method of manufacturing the solar cell module. In order to form the finger electrodes, the sintering conductive paste is coated on the acceptance surface side of anti-reflective film 7, and is also coated on the back surface side of p⁺-type diffused layer 43, by using the printing method such as the screen printing method or the offset printing method. It is possible to use silver paste containing silver powder, glass frit, an organic vehicle, and an organic solvent for the sintering conductive paste, for example. Here, the glass frit contains PbO, B₂O₃, and SiO₂ and therefore has an effect to promote sintering. Thereafter, the silver paste is baked at a high temperature around 700° C. The sintering conductive paste formed on anti-reflective film 7 penetrates anti-reflective film 7 by the action of glass frit, and thus the sintering conductive paste is connected to photoelectric converter 4. Meanwhile, the sintering conductive paste formed on p⁺-type diffused layer 43 is sintered. In this way, acceptance surface finger electrodes 51a and back surface finger electrodes 51b are formed. As shown in FIG. 2 and FIG. 3, multiple acceptance surface finger electrodes 51a and multiple back surface finger electrodes 51b are formed into lines at predetermined intervals over almost the entire area of photoelectric converter 4 on the acceptance surface side and on the back surface side.

FIG. 5B is another view showing the method of manufacturing the solar cell module. In order to form the bus-bar electrodes, the thermosetting conductive paste is coated on the acceptance surface side of anti-reflective film 7, and on the back surface side of p⁺-type diffused layer 43, by using the printing method such as the screen printing method or the offset printing method. It is possible to use silver paste formed by dispersing silver grains into an epoxy-based thermosetting resin solution is used for the thermosetting conductive paste, for example. Thereafter, the epoxy resin is hardened by heating the resin around 200° C. In this way, acceptance surface bus-bar electrodes 52a and back surface bus-bar electrodes 52b are formed.

As described above, acceptance surface finger electrodes 51a and acceptance surface bus-bar electrodes 52a are formed on the acceptance surface side of photoelectric converter 4, whereas back surface finger electrodes 51b and back surface bus-bar electrodes 52b are formed on the back surface side of photoelectric converter 4. In this embodiment, finger electrodes 51a are formed into a comb shape.

Next, a process is described in which acceptance surface bus-bar electrode 52a in first solar cell 10 is electrically coupled , by use of tab 3, to back surface bus-bar electrode 52b in second solar cell 10 adjacent to first solar cell 10. First, a conductive adhesive is inserted between acceptance surface bus-bar electrode 52a and tab 3, as well as between back surface side bus-bar electrode 52b and tab 3. Then, the electrodes 52a, 52b and tab 3 are bonded together by heating. Solder, thermosetting resin, and the like can be used as the conductive adhesive. The solder is formed into an alloy by heating, and constitutes the conductive adhesive layer. Meanwhile, the thermosetting resin is hardened by heating, and constitutes the conductive adhesive layer.

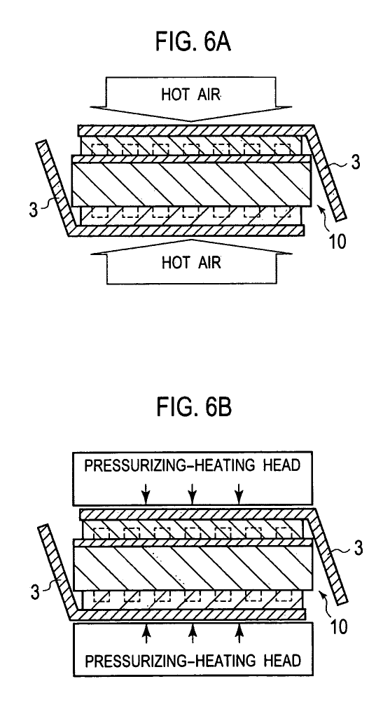

FIG. 6A is a view for explaining a thermal adhesion method using a heating device. By blowing hot air using the heating device, achieved is thermal adhesion between acceptance surface bus-bar electrode 52a and tab 3, as well as between back surface side bus-bar electrode 52b and tab 3. In this embodiment, the solder is coated on tab 3 in advance and the bus-bar electrodes are set in predetermined positions on solder-coated tab 3. Thereafter, the solder is melted and formed into an alloy by blowing hot air with the heating device. Thus, the bus-bar electrodes are fusion-bonded together with the solder. In this way, acceptance surface bus-bar electrode 52a is electrically coupled to back surface bus-bar electrode 52b through tab 3, and thereby collectively constitute the solar cell strings.

FIG. 6B is a view for explaining another thermal adhesion method. This example applies pressure bonding, in which acceptance surface bus-bar electrode 52a and back surface side bus-bar electrode 52b are bonded to tab 3 by applying pressure thereto. For example, acceptance surface bus-bar electrode 52a and back surface side bus-bar electrode 52b are pressure-bonded to tab 3 by pressing metal blocks that incorporated in a heater thereto. Here, it is also possible to achieve thermal compression bonding by heating pressuring heads at the time of pressure bonding. In this case, thermosetting resin sheets are also applicable. By inserting the thermosetting resin sheets between the bus-bar electrodes and the tab, it is possible to achieve thermal compression bonding.

Next, a laminated body is formed by laminating sealant 8, solar cell strings 20, sealant 8, and back surface protector 2 sequentially onto acceptance surface protector 1. Here, glass substrates are applicable to acceptance surface protector 1 and back surface protector 2. Meanwhile, EVA sheets are applicable to sealants 8.

Next, the laminated body is temporarily pressure-bonded in a vacuum atmosphere by heating and pressuring. Then, the EVA is completely hardened by heating the laminated body under a predetermined condition. In this way, solar cell module 100 is manufactured. Note that, it is also possible to attach a terminal box or an Al frame to solar cell module 100.

According to solar cell module 100 of this embodiment, the finger electrodes (acceptance surface finger electrodes 51a and back surface finger electrodes 51b) are formed by use of the sintering conductive paste, whereas the bus-bar electrodes (acceptance surface bus-bar electrodes 52a and back surface bus-bar electrodes 52b) are formed by use of the thermosetting conductive paste. Moreover, wiring tabs 3 for electrically connecting multiple solar cells 10 are electrically coupled between the bus-bar electrodes (acceptance surface bus-bar electrodes 52a and back surface bus-bar electrodes 52b).

In a conventional crystalline solar cell, the bus-bar electrode to which tab 3 is thermally bonded is generally made by use of the sintering conductive paste. On the contrary, according to solar cell 10 of this embodiment, the bus-bar electrode to which tab 3 is thermally bonded is made by use of the thermosetting conductive paste.

The thermosetting conductive paste is resin paste using thermosetting resin as binder. Meanwhile, the sintering conductive paste is silver paste containing silver powder, glass frit, an organic vehicle, and an organic solvent, for example. Therefore, the Young's modulus of the bus-bar electrode formed by use of the thermosetting conductive paste is smaller than the Young's modulus of the bus-bar electrode formed by use of the sintering conductive paste. That is, the bus-bar electrode formed by use of the thermosetting conductive paste has a smaller modulus of elasticity, and is therefore more deformable. Accordingly, this bus-bar electrode has smaller resistance against an external force, as compared to the bus-bar electrode formed by use of the sintering conductive paste. Therefore, cracks or brittle fractures hardly occur, even when stress is applied to the bus-bar electrode formed by use of the thermosetting conductive paste.

Here, tabs 3, the bus-bar electrodes (acceptance surface bus-bar electrodes 52a and back surface bus-bar electrodes 52b), and photoelectric converter 4 have mutually different linear expansion coefficients. Accordingly, stress is generated on an interface between tab 3 and the bus-bar electrode, as well as on an interface between the bus-bar electrode and photoelectric conductor 4, due to a temperature change occurring when tab 3 is thermally bonded to the bus-bar electrode.

However, as described above, the bus-bar electrode formed by use of the thermosetting conductive paste is more deformable than the bus-bar electrode formed by use of the sintering conductive paste. Therefore, an effect of the stress generated on the interfaces can be relaxed. As a result, it is possible to suppress occurrence of cracks or fractures in the bus-bar electrode or in photoelectric converter 4.

As described above, according to the crystalline solar cell of this embodiment, it is possible to relax the influence of the stress generated inside, and thereby to enhance reliability. Note that, the finger electrodes are formed by use of the sintering conductive paste having low specific resistance. Accordingly, a performance for collecting the carriers from the photoelectric conductor is well maintained.

Moreover, tab 3 is electrically coupled to the bus-bar electrode through the conductive adhesive layer formed by hardening the thermosetting resin sheet. Since the thermosetting resin retains viscoelasticity after hardening, it is possible to further relax the influence of the stress generated inside the crystalline solar cell.

The above embodiment has described the example of crystalline solar cell 10 having the pn junction formed by the thermal diffusion method. However, the invention is not limited only to this configuration. For example, the invention is also applicable to another solar cell made of GaAs or the like, which allows formation of collector electrodes by use of sintering conductive paste.

Moreover, in solar cell module 100 according to the above embodiment, the finger electrodes and the bus-bar electrodes are intersected together to form the comb shape. However, they are not necessarily intersected perpendicularly. For example, they may be intersected obliquely.

Further, in the above embodiment, back surface side finger electrodes 51b and back surface side bus-bar electrodes 52b are formed into the comb shape on the back surface side of photoelectric converter 4. Instead, it is also possible to form back surface collector electrode on the entire back surface of photoelectric converter 4. The stress generated when tabs 3 is bonded to acceptance surface bus-bar electrodes 52a is also relaxed in this case.

### EXAMPLE 1

Next, concrete example of this embodiment is described. First, an n-type semiconductor layer is formed, by diffusing P with the thermal diffusion method, on an acceptance surface of a 125-mm square p-type polycrystalline silicon substrate. Moreover, a p⁺-type diffused layer is formed by diffusing Al with the thermal diffusion method, on a back surface side of the p-type polycrystalline silicon substrate. Next, a SiN film (the anti-reflective film) is formed, by a plasma CVD method, on an acceptance surface of the n-type semiconductor layer.

Then, silver paste is coated into a line shape, by the screen printing method, on the acceptance surface side of the SiN film, as well as on the back surface side on the p⁺-type diffused layer. The silver paste used therein is formed by blending: 70 wt % of silver powder having grain sizes of 1 μmφ; 5 wt % of PbO—B₂O₃-based glass frit; and 25 wt % of an organic vehicle prepared by dissolving ethylcellulose into terpineol. Meanwhile, as for specifications of a plate used in the screen printing method, the aperture width of acceptance surface finger electrodes is set to 80 μm, while the aperture width of back surface finger electrodes is set to 120 μm. Thereafter, the silver paste is heated and sintered at 800° C., and thereby the acceptance surface finger electrodes and the back surface finger electrodes are formed.

Next, silver paste is coated into a line shape, by the screen printing method, on the acceptance surface side of the SiN film, as well as on the back surface side of the p⁺-type diffused layer. The silver paste used therein is formed by blending: 85 wt % of filler (which contains 50 wt % of spherical powder having grain sizes around 3 μmφ and 50 wt % of flake powder having grain sizes around 15 μmφ); 12 wt % of epoxy resin (molecular weight around 3500); and 3 wt % of termineol. Meanwhile, as for specifications of a plate used in the screen printing method, the aperture width is set to 1.5 mm. Thereafter, the epoxy resin is heated and hardened at 200° C. In this way, crystalline solar cells are fabricated.

Then, tabs coated with SnAgCu solder in a thickness of 30 μm is prepared, and a flux made of an organic solvent, rosin, a halogen element, and the like is coated thereon to remove oxides on surfaces of the tabs. A copper wire having a width of 2 mm and a thickness of 150 μm is used as the tabs.

Next, a first end of each tab is disposed above the acceptance surface bus-bar electrode of a crystalline solar cell, while a second end thereof is disposed below the back surface bus-bar electrode of the adjacent crystalline solar cell. In the state of sandwiching the solar cells with the tabs, the tabs and the bus-bar electrodes are thermally bonded together at 250° C. by blowing hot air thereon by use of the heating device shown in FIG. 6A. In this way, solar cell strings are fabricated.

Then, an EVA sheet, the solar cell strings, another EVA sheet, and a back surface film are sequentially laminated on a glass substrate serving as an acceptance surface protector of the solar cell module, and then the solar cell strings are sealed inside the EVA resin with a vacuum thermal compression bonding method. Thereafter, the EVA is cross-linked by storing the constituents inside a high-temperature tank at 150° C. for one hour. In this way, the solar cell module of Example 1 is manufactured.

### EXAMPLE 2

Here, different features from the manufacturing method of Example 1 is described.

In Example 2, thermosetting resin containing conductive particles is used as the conductive adhesive instead of the solder. To be more precise, the thermosetting resin having a width of 1.5 mm and a thickness of 20 μm is printed on the acceptance surface bus-bar electrodes and the back surface sub-bar electrodes with the screen sprinting method. The conductive adhesive is prepared by mixing fast curing epoxy resin with 5 wt % of silicone resin, and then by mixing 3 wt % of spherical Ni powder (grain sizes of 15 μmφ) therewith.

Next, a first end of each tab is disposed above the acceptance surface bus-bar electrode of a crystalline solar cell, while a second end thereof is disposed below the back surface bus-bar electrode of the adjacent crystalline solar cell. In the state of sandwiching the solar cells with the tabs, the tabs and the bus-bar electrodes are bonded together by pressurizing (1 kgf) and heating (200° C.) with the metal blocks of the heating device shown in FIG. 6B. A bottom surface of each metal block has dimensions of 130 mm×10 mm. In this way, the solar cell module of Example 2 is manufactured.

### COMPARATIVE EXAMPLE

In Comparative Example, the acceptance surface finger electrodes, the back surface finger electrodes, the acceptance surface bus-bar electrodes, and the back surface bus-bar electrodes are made of the sintering conductive paste. Conditions for formation thereof are similar to those specified in Example 1. Moreover, other configurations and manufacturing conditions are similar to those specified in Example 1.

### <Temperature Cycle Test>

The solar cell modules according to Examples 1 and 2 as well as Comparative Example are subjected to temperature cycle test (JIS C8917) to compare output characteristics of the solar cell modules before and after the tests.

In the temperature cycle test, a continuous 200-cycle test and a continuous 400-cycle test are carried out. Here, in accordance with the JIS standard, changing temperature from a high temperature (90° C.) to a low temperature (−40° C.), or from the low temperature to the high temperature is set as one cycle. In this way, the output characteristics are measured after the test.

### <Results>

Results of measurement concerning Examples 1 and 2 as well as Comparative Example are shown below in a table. Note that the output characteristics are expressed in relative values on the assumption that each output characteristic before the test is defined as 100%.

| | After 200 cycles | After 400 cycles |
|---|---|---|
| Example 1 | 99.0% | 98.0% |
| Example 2 | 99.3% | 98.7% |
| Comparative Example | 97.3% | 94.7% |

After 400 cycles, an output decreasing rate in Example 1 is reduced by 3.3% as compared to Comparative Example. This is because the bus-bar electrodes (acceptance surface bus-bar electrodes 52a and back surface bus-bar electrodes 52b) are formed by use of the thermosetting conductive paste, whereby suppressed is an influence of the stress generated on an interface between the tab and the bus-bar electrode, as well as on an interface between the bus-bar electrode and the photoelectric converter.

Meanwhile, after 400 cycles, a decreasing rate in Example 2 is reduced by 4.0% as compared to Comparative Example. This is because the stress generated on the interface between the tab and the bus-bar electrode is further relaxed by using the thermoplastic resin sheets as the conductive adhesive instead of the solder used in Example 1.

As described above, according to this embodiment, the bus-bar electrode to which the tab is thermally bonded is formed by use of the thermosetting conductive paste. The bus-bar electrode formed by use of the thermosetting conductive paste has a more deformable property than that of the bus-bar electrode formed by use of the sintering conductive paste. Therefore, it is possible to relax an influence of stress generated on an interface between the tab and the bus-bar electrode, as well as on an interface between the bus-bar electrode and the photoelectric converter. As a result, occurrence of cracks or fractures in the bus-bar electrode or in the photoelectric converter can be suppressed.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

What is claimed is:

1. A solar cell comprising:
a photoelectric converter configured to generate carriers by photoelectric conversion;
a plurality of finger electrodes electrically coupled to the photoelectric converter and configured to collect carriers generated in the photoelectric converter, the finger electrodes comprising a sintering conductive material as an essential ingredient; and
a bus-bar electrode electrically coupled to the plurality of finger electrodes and configured to collect the carriers from the finger electrodes, the bus-bar electrode comprising a thermosetting conductive material as an essential ingredient.

2. The solar cell of claim 1, wherein the sintering conductive material is ceramic paste.

3. The solar cell of claim 1, wherein the sintering conductive material comprises silver paste containing silver powder, glass frit, an organic vehicle, and an organic solvent.

4. The solar cell of claim 1, wherein the thermosetting conductive material comprises resin paste with thermosetting resin binder.

5. The solar cell of claim 1, wherein the thermosetting conductive material comprises silver paste prepared by dispersing silver grains into an epoxy-based thermosetting resin solution.

6. A solar cell module comprising:
at least two solar cells, each comprising:
a photoelectric converter configured to generate carriers by photoelectric conversion;
a plurality of finger electrodes electrically coupled to the photoelectric converter and configured to collect carriers generated in the photoelectric converter, the finger electrodes comprising a sintering conductive material as an essential ingredient; and
a bus-bar electrode electrically coupled to the plurality of finger electrodes and configured to collect the carriers from the finger electrodes, the bus-bar electrode comprising a thermosetting conductive material as an essential ingredient;
a tab configured to electrically interconnect the solar cells by electrically connecting the bus-bar electrodes to one another;
an acceptance surface protector provided on an acceptance surface side of the solar cells; and
a back surface protector provided on a back surface side of the solar cells.

7. The solar cell module of claim 6, further comprising a conductive adhesive layer formed on the bus-bar electrode, the conductive adhesive layer comprising a resin of conductive particles,
wherein the tab is electrically coupled to the bus-bar electrode through the conductive adhesive layer.
